(19) United States
(12) Patent Application Publication
(10) Pub. No.: US 2017/0170378 A1
(43) Pub. Date: Jun. 15, 2017

(54) THERMOELECTRIC MODULE

(71) Applicant: National Tsing Hua University, Hsinchu City (TW)

(72) Inventors: Chien-Neng Liao, Taichung (TW); Meng-Pei Lu, Taipei City (TW); Ming-Chi Tai, Hsinchu City (TW); Li-Chi Chen, New Taipei City (TW); Hung-Hsien Huang, Kaohsiung City (TW)

(21) Appl. No.: 15/065,882

(22) Filed: Mar. 10, 2016

(30) Foreign Application Priority Data
Dec. 10, 2015 (TW) 104141465

(51) Int. Cl. H01L 35/02; H01L 35/22; H01L 35/16

(52) U.S. Cl. CPC H01L 35/02; H01L 35/16; H01L 35/22

(57) ABSTRACT

A thermoelectric module including at least one PN junction device is provided. The PN junction device includes a PN junction structure, top electrodes and at least one bottom electrode. The PN junction structure includes an N-type thermoelectric element and a P-type thermoelectric element, wherein side surfaces of the N-type thermoelectric element and the P-type thermoelectric element facing each other are in contact. The top electrodes are separated from each other and respectively cover a portion of a top surface of the N-type thermoelectric element or a portion of a top surface of the P-type thermoelectric element. The bottom electrode covers a bottom surface of the N-type thermoelectric element and a bottom surface of the P-type thermoelectric element.

### CROSS-REFERENCE TO RELATED APPLICATION

This application claims the priority benefit of Taiwan application serial no. 104141465, filed on Dec. 10, 2015. The entirety of the above-mentioned patent application is hereby incorporated by reference herein and made a part of this specification.

### BACKGROUND OF THE INVENTION

1. Field of the Invention

The present invention generally relates to a thermoelectric module, and more particularly, to a thermoelectric module of transverse output voltage.

2. Description of Related Art

Many industries are required to use a lot of energy and generate considerable heat during manufacturing processes, thereby causing a large amount of energy wasted. A common thermoelectric module can use a temperature difference to generate power, advantages thereof are occupying small space and low maintenance costs, and thus is suitable for recovering industrial waste heat to avoid energy waste.

However, common traditional thermoelectric module can only generate an electric field parallel to a temperature difference direction and is difficult to adjust a thermoelectric efficacy of the module by changing sizes of P-type and N-type thermoelectric elements in the module, and thus is required to connect in series with a lots of P-type and N-type thermoelectric materials so as to obtain a higher output voltage under a fixed temperature difference.

### SUMMARY OF THE INVENTION

The invention is directed to a thermoelectric module capable of effectively enhancing a module efficiency.

The invention provides a thermoelectric module including at least one PN junction device. The PN junction device includes a PN junction structure, top electrodes and at least one bottom electrode. The PN junction structure includes an N-type thermoelectric element and a P-type thermoelectric element, wherein side surfaces of the N-type thermoelectric element and the P-type thermoelectric element facing each other are in contact. The top electrodes are separated from each other and respectively cover a portion of a top surface of the N-type thermoelectric element or a portion of a top surface of the P-type thermoelectric element. The bottom electrode covers a bottom surface of the N-type thermoelectric element and a bottom surface of the P-type thermoelectric element.

According to one embodiment of the invention, in the thermoelectric module, the N-type thermoelectric element and the P-type thermoelectric element may include semiconductor materials, and a charge carrier concentration thereof, for example, ranges between 10¹⁸ cm⁻³ and 10²¹ cm⁻³.

According to one embodiment of the invention, in the thermoelectric module, a material of the N-type thermoelectric element may be BiTe based thermoelectric material, PbTe based thermoelectric material or SiGe based thermoelectric material.

According to one embodiment of the invention, in the thermoelectric module, a material of the P-type thermoelectric element may be BiTe based thermoelectric material, PbTe based thermoelectric material or SiGe based thermoelectric material.

According to one embodiment of the invention, in the thermoelectric module, materials of the top electrodes and the bottom electrode may respectively include metal or conductive metal composite material.

According to one embodiment of the invention, in the thermoelectric module, the N-type thermoelectric element and the P-type thermoelectric element may respectively be strip-shaped, arc-shaped or ring-shaped.

According to one embodiment of the invention, in the thermoelectric module, the N-type thermoelectric element and the P-type thermoelectric element may constitute a strip-shape, an arc-shape or a ring-shape.

According to one embodiment of the invention, in the thermoelectric module, when the N-type thermoelectric element and the P-type thermoelectric element are respectively arc-shaped or ring-shaped, or when the N-type thermoelectric element and the P-type thermoelectric element constitute an arc-shape or a ring-shape, the PN junction device can be applied to a tubular heat source.

According to one embodiment of the invention, in the thermoelectric module, the top electrodes and the bottom electrode may respectively be strip-shaped, arc-shaped or ring-shaped.

According to one embodiment of the invention, in the thermoelectric module, the number of the at least one bottom electrode in one PN junction device can be one, and the bottom electrode may completely cover or partially cover the bottom surface of the N-type thermoelectric element and the bottom surface of the P-type thermoelectric element the bottom electrode.

According to one embodiment of the invention, in the thermoelectric module, the number of the at least one PN junction structure may be a plurality, the PN junction structures may be disposed separately, and in two adjacent PN junction structures, the top surface of the N-type thermoelectric element and the top surface of the P-type thermoelectric element separated from each other are connected by the top electrode, and the adjacent bottom electrodes do not contact each other.

According to one embodiment of the invention, in the thermoelectric module, the number of the at least one bottom electrode in one PN junction device may be a plurality, and the bottom electrodes may be separated from each other and respectively cover a portion of the bottom surface of the N-type thermoelectric element or a portion of the bottom surface of the P-type thermoelectric element.

According to one embodiment of the invention, in the thermoelectric module, in the same PN junction device, the bottom electrodes can have an opening therebetween that exposes a portion of the bottom surface of the N-type thermoelectric element and a portion of the bottom surface of the P-type thermoelectric element.

According to one embodiment of the invention, in the thermoelectric module, the number of the at least one PN junction structure may be a plurality, the PN junction structures may be disposed separately, and the top surface of the N-type thermoelectric element and the bottom surface of the P-type thermoelectric element in one PN junction structure are respectively connected to the top surface of the P-type thermoelectric element and the bottom surface of the N-type thermoelectric element at a side through the top electrode and the bottom electrode.

According to one embodiment of the invention, in the thermoelectric module, the bottom surface of the N-type thermoelectric element and the top surface of the P-type thermoelectric element in the one PN junction structure are respectively connected to the bottom surface of the P-type thermoelectric element and the top surface of the N-type thermoelectric element at another side by the bottom electrode and the top electrode.

According to one embodiment of the invention, in the thermoelectric module, a method for connecting the top electrodes with the at least one PN junction structure can include solder bonding or direct pressing.

According to one embodiment of the invention, in the thermoelectric module, a method for connecting the bottom electrode with the at least one PN junction structure can include solder bonding or direct pressing.

According to one embodiment of the invention, in the thermoelectric module, in the same PN junction device, the top electrodes can have an opening therebetween that exposes a portion of the top surface of the N-type thermoelectric element and a portion of the top surface of the P-type thermoelectric element.

In view of the above, in the thermoelectric module provided by the invention, with the design of connecting the side surfaces of the N-type thermoelectric element and the P-type thermoelectric element facing each other and the configuration of the top electrodes being separated from each other and respectively covering a portion of the top surface of the N-type thermoelectric element or a portion of the top surface of the P-type thermoelectric element, a transverse temperature gradient perpendicular to a temperature difference direction of a cold end and a hot end can be generated; that is, a two-dimensional temperature gradient can be formed in the PN junction structure, and thus an effect of guiding carrier flow can be provided so that a greater output voltage can be obtained under a fixed temperature difference, thereby enhancing the module efficiency.

Several exemplary embodiments accompanied with figures are described in detail below to further describe the disclosure in details.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a thermoelectric module according to a first embodiment of the invention.

FIG. 2 is a schematic diagram illustrating a thermoelectric module according to a second embodiment of the invention.

FIG. 3 is a schematic diagram illustrating a thermoelectric module according to a third embodiment of the invention.

FIG. 4 is a schematic diagram illustrating a thermoelectric module according to a fourth embodiment of the invention.

FIG. 5 is a schematic diagram illustrating a thermoelectric module according to a fifth embodiment of the invention.

FIG. 6 is a schematic diagram illustrating a thermoelectric module according to a sixth embodiment of the invention.

FIG. 7 is a schematic diagram illustrating a thermoelectric module according to a seventh embodiment of the invention.

FIG. 8 is a schematic diagram illustrating a thermoelectric module according to an eighth embodiment of the invention.

### DESCRIPTION OF THE EMBODIMENTS

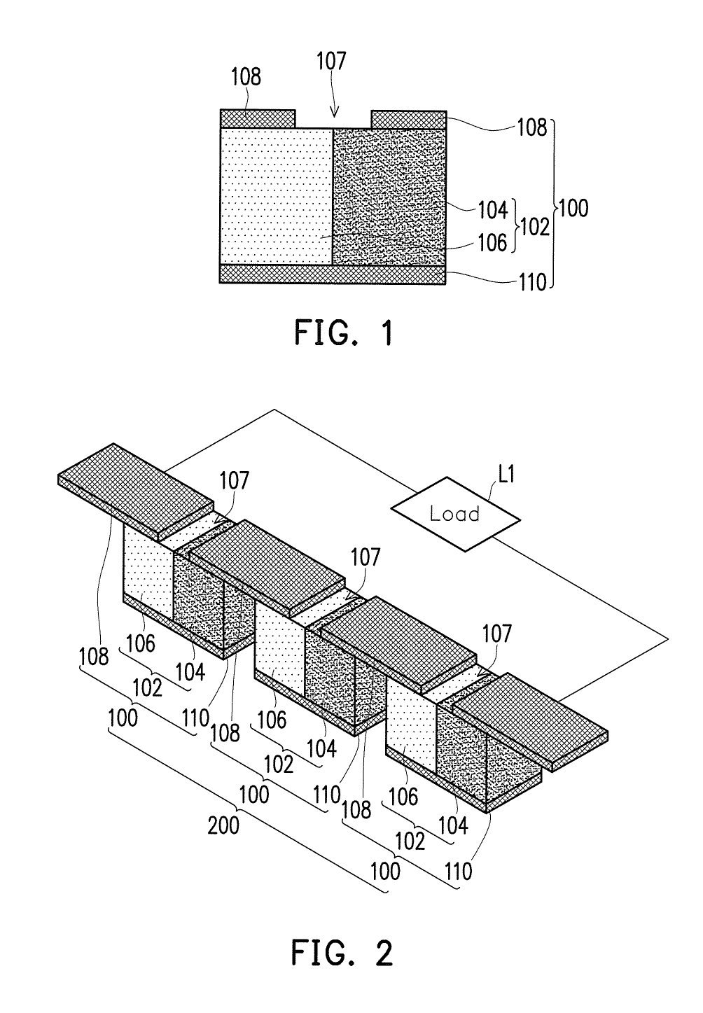

FIG. 1 is a schematic diagram illustrating a thermoelectric module according to a first embodiment of the invention.

Referring to FIG. 1, the thermoelectric module includes at least one PN junction device 100. In the present embodiment, the thermoelectric module including one PN junction device 100 is used as an example for the description; that is, one PN junction device 100 can be adopted as the smallest unit in the thermoelectric module, but the invention is not limited thereto. In other embodiments, the thermoelectric module may also include PN junction devices 100.

One PN junction device 100 includes a PN junction structure 102, top electrodes 108 and at least one bottom electrode 110. In the first embodiment, one PN junction device 100 including one bottom electrode 110 is used as an example for the description, but the invention is not limited thereto. In other embodiments, one PN junction device 100 may also include bottom electrodes 110.

The PN junction structure 102 includes an N-type thermoelectric element 104 and a P-type thermoelectric element 106, and side surfaces of the N-type thermoelectric element 104 and the P-type thermoelectric element 106 facing each other are in contact. In the present embodiment, the side surfaces of the N-type thermoelectric element 104 and the P-type thermoelectric element 106 facing each other being completely in contact is used as an example for the description, but the invention is not limited thereto. The N-type thermoelectric element 104 and the P-type thermoelectric element 106 may be semiconductor materials, and a charge carrier concentration thereof may, for example, range between 10¹⁸ cm⁻³ and 10²¹ cm⁻³. When the charge carrier concentration of the semiconductor materials is higher than 10²¹ cm⁻³, a Seebeck coefficient would be too small. When the charge carrier concentration is lower than 10¹⁸ cm⁻³, an electrical resistance would be too high. The material of the N-type thermoelectric element 104 may be a normal-temperature thermoelectric material (e.g., BiTe based thermoelectric material), a medium-temperature thermoelectric material (e.g., PbTe based thermoelectric material) or a high-temperature thermoelectric material (e.g., SiGe based thermoelectric material). The material of the P-type thermoelectric element 106 may be a normal-temperature thermoelectric material (e.g., BiTe based thermoelectric material), a medium-temperature thermoelectric material (e.g., PbTe based thermoelectric material) or a high-temperature thermoelectric material (e.g., SiGe based thermoelectric material). However, the invention is not limited by the aforesaid materials of the N-type thermoelectric element 104 and the P-type thermoelectric element 106, such that any thermoelectric material system with a charge carrier concentration within the aforesaid range can be adopted.

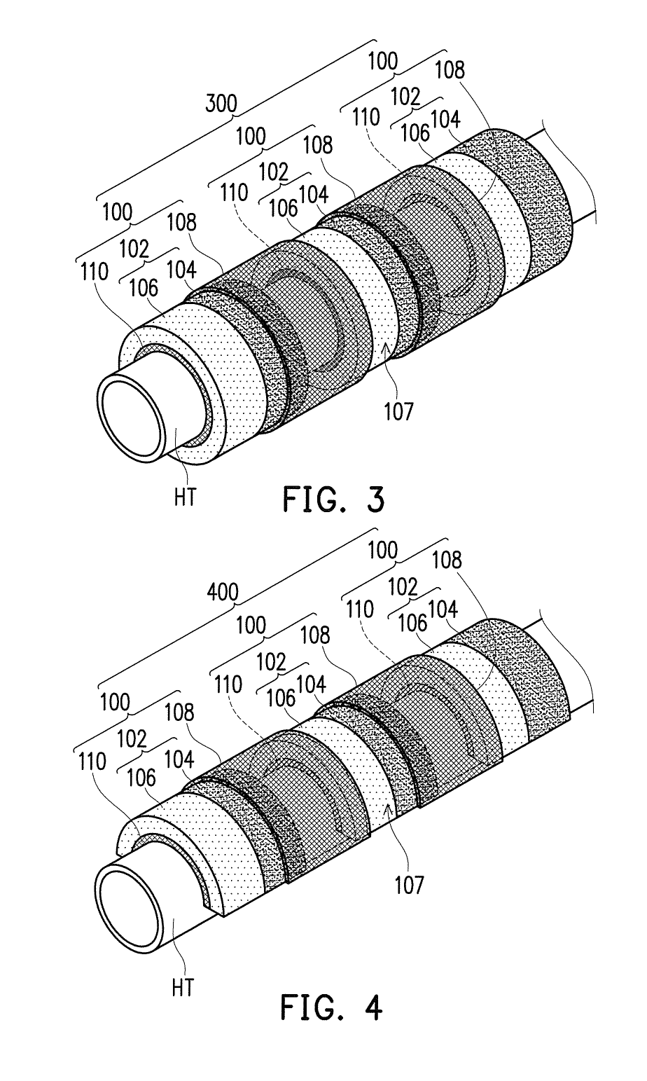

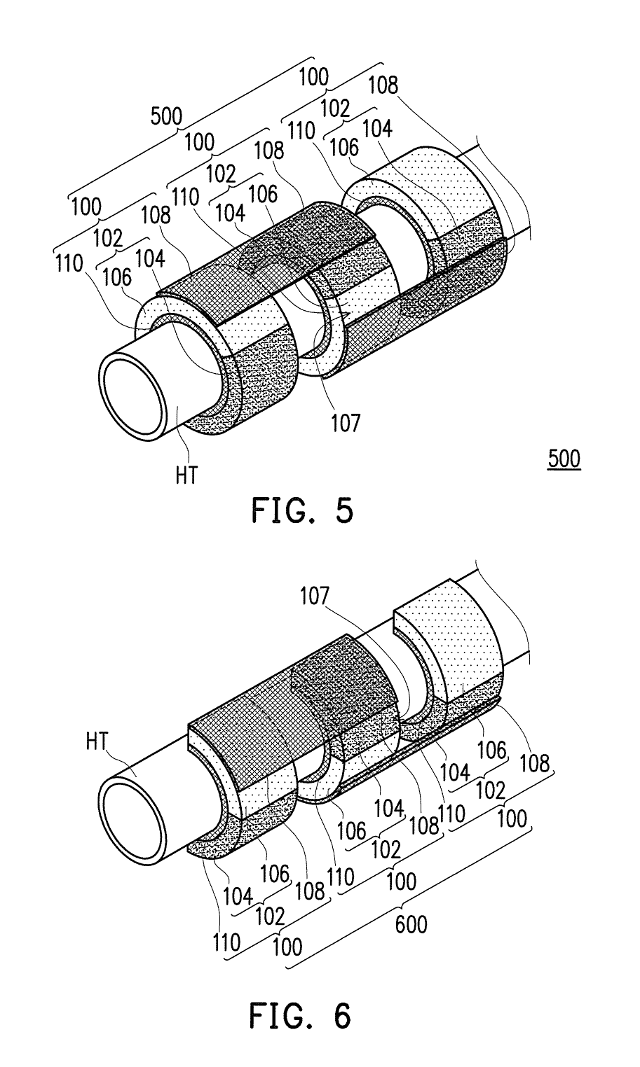

The N-type thermoelectric element 104 and the P-type thermoelectric element 106 may respectively be strip-shaped, arc-shaped or ring-shaped, and the N-type thermoelectric element 104 and the P-type thermoelectric element 106 can constitute a strip-shape, an arc-shape or a ring-shape. In the present embodiment, the N-type thermoelectric element 104 and the P-type thermoelectric element 106 being strip-shaped, and the N-type thermoelectric element 104 and the P-type thermoelectric element 106 constituting a strip-shape, are used as an example for the description. In addition, when the N-type thermoelectric element 104 and the P-type thermoelectric element 106 are arc-shaped or ring-shaped (referring to FIG. 3 and FIG. 4), or when the N-type thermoelectric element 104 and the P-type thermoelectric element 106 constitute the arc-shape or the ring-shape (referring to FIG. 5 and FIG. 6), the PN junction device 100 may be applied to a commonly seen tubular heat source, such as a hot water pipe or a waste gas pipe.

The top electrodes 108 are separated from each other and respectively cover a portion of a top surface of the N-type thermoelectric element 104 or a portion of a top surface of the P-type thermoelectric element 106, and thus there is an opening 107 exposing a portion of the top surface of the N-type thermoelectric element 104 and a portion of the top surface of the P-type thermoelectric element 106 between the top electrodes 108. In addition, in the same PN junction device 100, one top electrode 108 only covers a portion of the top surface of the one of the N-type thermoelectric element 104 and the P-type thermoelectric element 106. In other words, in the same PN junction device 100, one top electrode 108 does not simultaneously cover the N-type thermoelectric element 104 and the P-type thermoelectric element 106. The top electrodes 108 may be made of metal or a conductive metal composite material with an electrical resistance, for example, lower than 10⁻⁶ Ω·m. The top electrodes 108 may be strip-shaped, arc-shaped or ring-shaped. In the present embodiment, the top electrodes 108 being strip-shaped are used as an example for the description.

The bottom electrode 110 covers a bottom surface of the N-type thermoelectric element 104 and a bottom surface of the P-type thermoelectric element 106. The bottom electrode 110 may completely cover or partially cover the bottom surface of the

N-type thermoelectric element 104 and the bottom surface of the P-type thermoelectric element 106 in the PN junction structure 102; as long as the bottom electrode 110 simultaneously covers the bottom surface of the N-type thermoelectric element 104 and the bottom surface of the P-type thermoelectric element 106 to enable the N-type thermoelectric element 104 and the P-type thermoelectric element 106 to from an equipotential at portions nearby the bottom electrode 110, it will be fine. The bottom electrode 110 may be made of metal or a conductive metal composite material. The bottom electrode 110 may be strip-shaped, arc-shaped or ring-shaped. In the present embodiment, the bottom electrode 110 being strip-shaped is used as an example for the description.

Methods for connecting the top electrodes 108 and the bottom electrode 110 with the PN junction structure 102 can respectively be solder bonding or direct pressing. In the present embodiment, when adopting the method of direct pressing to perform the connecting, the use of solder can be avoided, and thereby prevent the overall application temperature range of the PN junction device 100 from being affected by a heat resistance limitation of the solder.

One of the top electrodes 108 and the bottom electrode 110 is close to a hot end, while the other one is close to a cold end. In the present embodiment and other embodiments in the following, the top electrodes 108 being close to the cold end and the bottom electrode 110 being close to the hot end are used as an example for the description, but the invention is not limited thereto. In other words, the top electrodes 108 may also be close to the hot end and the bottom electrode 110 may also be close to the cold end.

As compared to the N-type thermoelectric element 104 and the P-type thermoelectric element 106 under the top electrodes 108, the N-type thermoelectric element 104 and the P-type thermoelectric element 106 under the opening 107 are not covered by the top electrodes 108 and will be in contact with air. Since a thermal conductivity of the air is smaller than that of the top electrodes 108, the N-type thermoelectric element 104 and the P-type thermoelectric element 106 will generate a transverse temperature gradient between the regions covered and not covered by the top electrodes 108. Wherein, a direction of the transverse temperature gradient is perpendicular to a temperature difference direction of the cold end and the hot end; that is, a two-dimensional temperature gradient may be formed in the PN junction structure 102. Since the transverse temperature gradient can generate a transverse voltage gradient on the direction thereof, an effect of guiding the carrier to flow towards the top electrodes 108 is provided. Therefore, under a condition of having a fixed temperature difference, with the two-dimensional temperature gradient formed in the PN junction structure 102, a greater output voltage can be obtained between the top electrodes 108, and thereby enhances a module efficiency.

In addition, with the transverse voltage gradient, a transverse current perpendicular to the temperature difference direction of the cold end and the hot end can be generated. The transverse current can flow from the P-type thermoelectric element 106 to the N-type thermoelectric element 104, and be outputted through the top electrodes 108. Therefore, the transverse current generated by the PN junction device 100 of the present embodiment only has to pass through the two top electrodes 108, and can reduce the amount of contacts that current passing through as compared to a conventional thermoelectric module, so as to lower a total resistance of the thermoelectric module and to enhance the output voltage for enhancing the module efficiency.

Moreover, the PN junction device 100 only requires to be assembled with wirings at the side of top electrodes 108, and thus the structure and the shape of the PN junction device 100 is more flexible.

It can be known from the above embodiment that, with the design of connecting the side surfaces of the N-type thermoelectric element 104 and the P-type thermoelectric element 106 facing each other and the configuration of the top electrodes 108 being separated from each other and respectively covering a portion of the top surface of the N-type thermoelectric element 104 or a portion of the top surface of the P-type thermoelectric element 106, the transverse temperature gradient perpendicular to the temperature difference direction of the cold end and the hot end can be generated; that is, the two-dimensional temperature gradient can be formed in the PN junction structure 102, and thus the effect of guiding carrier flow can be provided so that a greater output voltage can be obtained under the fixed temperature difference, thereby enhancing the module efficiency.

FIG. 2 is a schematic diagram illustrating a thermoelectric module according to a second embodiment of the invention.

Referring to FIG. 1 and FIG. 2 at the same time, differences between the second embodiment and the first embodiment are indicated hereinafter. The thermoelectric module 200 in the second embodiment includes PN junction devices 100 and PN junction structures 102. The PN junction structures 102 are disposed separately; and in two adjacent PN junction structures 102, the top surface of the N-type thermoelectric element 104 and the top surface of the P-type thermoelectric element 106 that are separated from each other are connected by the top electrode 108, and the adjacent bottom electrodes 110 do not contact each other. In addition, same components in the second embodiment and the first embodiment are indicated by the same reference numerals, and descriptions thereof are omitted.

In the thermoelectric module 200, the PN junction devices 100 are connected through the aforementioned method, so that the transverse current perpendicular to the temperature difference direction of the cold end and the hot end can be outputted through the top electrodes 108. Therefore, when connecting the top electrodes 108 at the two ends to a load L1, a set of voltages can be outputted.

FIG. 3 is a schematic diagram illustrating a thermoelectric module according to a third embodiment of the invention.

Referring to FIG. 2 and FIG. 3 at the same time, differences between the third embodiment and the second embodiment are indicated hereinafter. In the thermoelectric module 300 of the third embodiment, the N-type thermoelectric elements 104 and the P-type thermoelectric elements 106 in the PN junction devices 100 are respectively ring-shaped. In addition, the top electrodes 108 and the bottom electrodes 110 may also respectively be ring-shaped, but the invention is not limited thereto. The bottom electrodes 110 are located at inner sides of the PN junction structures 102, and the top electrodes 108 are located on outer sides of the PN junction structures 102. In addition,same components in the third embodiment and the second embodiment are indicated by the same reference numerals, and descriptions thereof are omitted.

The third embodiment is a practical example of applying the thermoelectric module 300 to a tubular heat source HT, wherein the thermoelectric module 300 is sleeved on the tubular heat source HT.

FIG. 4 is a schematic diagram illustrating a thermoelectric module according to a fourth embodiment of the invention.

Referring to FIG. 2 and FIG. 4 at the same time, differences between the fourth embodiment and the second embodiment are indicated hereinafter. In the thermoelectric module 400 of the fourth embodiment, the N-type thermoelectric elements 104 and the P-type thermoelectric elements 106 in the PN junction devices 100 are respectively arc-shaped. In addition, the top electrodes 108 and the bottom electrodes 110 may also respectively be arc-shaped, but the invention is not limited thereto. The bottom electrodes 110 are located at the inner sides of the PN junction structures 102 and the top electrodes 108 are located on the outer sides of the PN junction structure 102. In addition, same components in the fourth embodiment and the second embodiment are indicated by the same reference numerals, and descriptions thereof are omitted.

The fourth embodiment is a practical example of applying the thermoelectric module 400 to a tubular heat source HT. In the present embodiment, the illustration is provided with one set of the thermoelectric module 400 being sleeved onto the tubular heat source HT for an example; however, in other embodiments, two sets of the thermoelectric modules 400 may also be separately sleeved onto the tubular heat source HT, and the invention is not limited thereto. Those skilled in the art should be able to adjust the number of the thermoelectric modules 400 being sleeved onto the tubular heat source HT based on design requirements of actual products; nevertheless, it falls within the scope of the present invention as long as there is more than one set of the thermoelectric module 400 being sleeved onto the tubular heat source HT.

FIG. 5 is a schematic diagram illustrating a thermoelectric module according to a fifth embodiment of the invention.

Referring to FIG. 2 and FIG. 5 at the same time, differences between the fifth embodiment and the second embodiment are indicated hereinafter. In the thermoelectric module 500 of the fifth embodiment, the N-type thermoelectric elements 104 and the P-type thermoelectric elements 106 in the PN junction devices 100 constitute ring-shapes. In addition, the top electrodes 108 may be arc-shaped, and the bottom electrodes 110 may be ring-shaped, but the invention is not limited thereto. The bottom electrodes 110 are located at the inner sides of the PN junction structures 102 and the top electrodes 108 are located on the outer sides of the PN junction structures 102. In addition, same components in the fifth embodiment and the second embodiment are indicated by the same reference numerals, and descriptions thereof are omitted.

The fifth embodiment is a practical example of applying the thermoelectric module 500 to a tubular heat source HT, wherein the thermoelectric module 500 is sleeved on the tubular heat source HT.

FIG. 6 is a schematic diagram illustrating a thermoelectric module according to a sixth embodiment of the invention.

Referring to FIG. 2 and FIG. 6 at the same time, differences between the sixth embodiment and the second embodiment are indicated hereinafter. In the thermoelectric module 600 of the sixth embodiment, the N-type thermoelectric elements 104 and the P-type thermoelectric elements 106 in the PN junction devices 100 constitute arc-shapes. In addition, the top electrodes 108 and the bottom electrodes 110 may also respectively be arc-shaped, but the invention is not limited thereto. The bottom electrodes 110 are located at the inner sides of the PN junction structures 102 and the top electrodes 108 are located on the outer sides of the PN junction structures 102. In addition, same components in the sixth embodiment and the second embodiment are indicated by the same reference numerals, and descriptions thereof are omitted.

The sixth embodiment is a practical example of applying the thermoelectric module 600 to a tubular heat source HT. In the present embodiment, the illustration is provided with one set of the thermoelectric module 600 being sleeved onto the tubular heat source HT for an example; however, in other embodiments, two sets of the thermoelectric module 600 may also be separately sleeved onto the tubular heat source HT, and the invention is not limited thereto. Those skilled in the art should be able to adjust the number of the thermoelectric modules 600 being sleeved onto the tubular heat source HT based on design requirements of actual products; nevertheless, it falls within the scope of the present invention as long as there is more than one set of the thermoelectric module 600 being sleeved onto the tubular heat source HT.

In addition, the method of outputting the voltage to the load by the thermoelectric module in the first embodiment and in the third to sixth embodiments can be referred to the descriptions of the second embodiment, and thus will not be repeated herein.

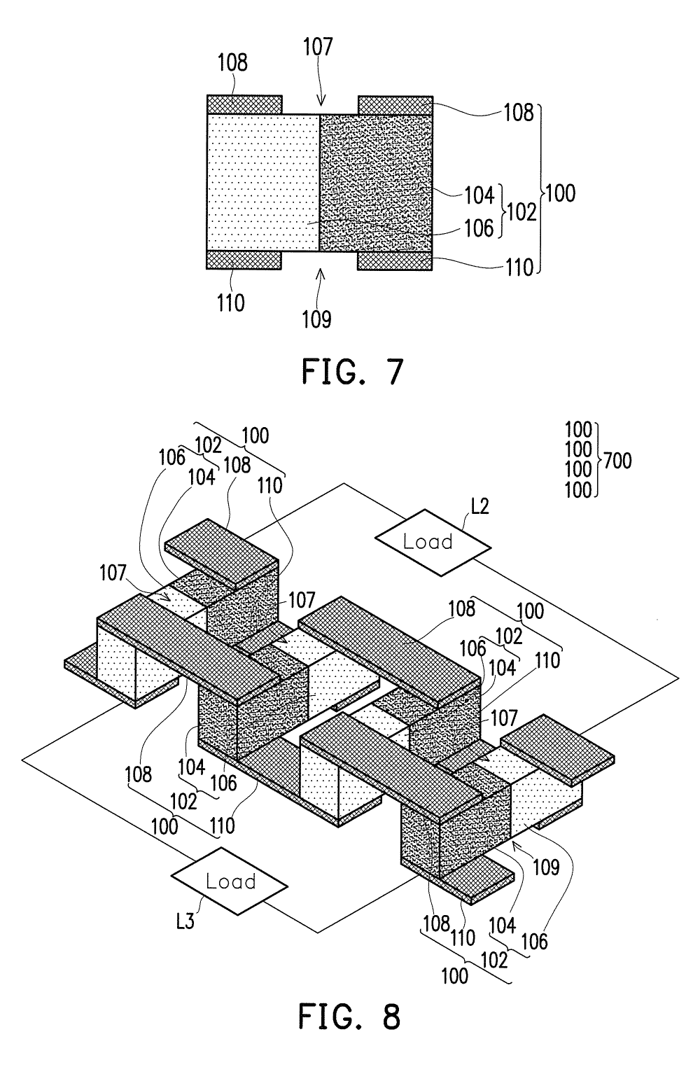

FIG. 7 is a schematic diagram illustrating a thermoelectric module according to a seventh embodiment of the invention.

Referring to FIG. 1 and FIG. 7 at the same time, differences between the seventh embodiment and the first embodiment are indicated hereinafter. In the seventh embodiment, the thermoelectric module may include at least one PN junction device 700. Each PN junction device 700 includes bottom electrodes 110. The bottom electrodes 110 are separated from each other and respectively cover a portion of the bottom surface of the N-type thermoelectric element 104 or a portion of the bottom surface of the P-type thermoelectric element 106, and there is an opening 109 between the bottom electrodes 110. In addition, in the same PN junction device 700, one bottom electrode 110 only covers a portion of the bottom surface of one of the N-type thermoelectric element 104 and the P-type thermoelectric element 106. In other words, in the same PN junction device 700, one bottom electrode 110 does not simultaneously cover the N-type thermoelectric element 104 and the P-type thermoelectric element 106. In the present embodiment, the thermoelectric module including one PN junction device 700 is used as an example for the description; that is, one PN junction device 700 can be adopted as the smallest unit in the thermoelectric module, but the invention is not limited thereto. In other embodiments, the thermoelectric module may also include PN junction devices 700. In addition, same components in the seventh embodiment and the first embodiment are indicated by the same reference numerals, and descriptions thereof are omitted.

Similar to the condition of the first embodiment shown in FIG. 1, the PN junction device 700 may generate a transverse temperature gradient between regions covered and not covered by the top electrodes 108 via the opening 107, so as to form a transverse voltage gradient in the PN junction structure 102 at nearby the top electrodes 108. Similarly, the PN junction device 700 may generate the transverse temperature gradient between regions covered and not covered by the bottom electrodes 110 via the opening 109, so as to generate another transverse voltage gradient in the PN junction structure 102 at nearby the bottom electrodes 110. Therefore, the thermoelectric module 700 can output a set of voltages respectively through the top electrodes 108 and the bottom electrodes 110.

FIG. 8 is a schematic diagram illustrating a thermoelectric module according to an eighth embodiment of the invention. Referring to FIG. 7 and FIG. 8 at the same time, differences between the eighth embodiment and the seventh embodiment are indicated hereinafter. In the present embodiment, thermoelectric module 800 includes PN junction devices 700 that are disposed separately. The number of the PN junction structure 102 is a plurality, and the PN junction structure 102 are disposed separately. The top surface of the N-type thermoelectric element 104 and the bottom surface of the

P-type thermoelectric element 106 in one PN junction structure 102 are respectively connected to the top surface of the P-type thermoelectric element 106 and the bottom surface of the N-type thermoelectric element 104 at a side through the top electrode 108 and the bottom electrode 110. In addition, the bottom surface of the N-type thermoelectric element 104 and the top surface of the P-type thermoelectric element 106 in the same PN junction structure 102 are respectively connected to the bottom surface of the P-type thermoelectric element 106 and the top surface of the N-type thermoelectric element 104 at another side through the bottom electrode 110 and the top electrode 108. In addition, same components in the eighth embodiment and the seventh embodiment are indicated by the same reference numerals, and descriptions thereof are omitted.

In the thermoelectric module 800, the PN junction devices 700 are connected through the aforementioned method, and top portions of the PN junction structures 102 nearby the top electrodes 108 and bottom portions of the PN junction structures 102 nearby the bottom electrodes 110 can each generate a transverse current, and the transverse currents from the top portions of the PN junction structures 102 are transmitted and outputted through the top electrodes 108 while the transverse currents from the bottom portions of the PN junction structures 102 are transmitted and outputted through the bottom electrodes 110. Therefore, when connecting the top electrodes 108 at the two ends to a load L2, a set of voltages can be outputted. When connecting the bottom electrodes 110 at the two ends to a load L3, another set of voltages can be outputted. Moreover, the method of outputting the voltage to the load by the thermoelectric module in the seventh embodiment can be referred to the descriptions of the eighth embodiment, and thus will not be repeated herein.

On the other hand, in the aforementioned first to eighth embodiments, the thermoelectric module generating power through using a temperature difference is used as an example for the description, but the invention is not limited thereto. Those skilled in the art should also be able to input currents to the thermoelectric modules in the aforementioned embodiments for the purpose of cooling or heat dissipation.

In summary, the thermoelectric modules provided in the aforementioned embodiments at least have the following features. With the design of connecting the side surfaces of the N-type thermoelectric element and the P-type thermoelectric element facing each other and the configuration of the top electrodes being separated from each other and respectively covering a portion of the top surface of the N-type thermoelectric element or a portion of the top surface of the P-type thermoelectric element, a transverse temperature gradient perpendicular to a temperature difference direction of the cold end and the hot end can be generated; that is, a two-dimensional temperature gradient can be formed in the PN junction structure, and thus the effect of guiding the carrier flow can be provided so that a greater output voltage can be obtained under a fixed temperature difference, thereby enhancing the module efficiency.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thermoelectric module, comprising at least one PN junction device, wherein the PN junction device comprises:
a PN junction structure, comprising:
an N-type thermoelectric element; and
a P-type thermoelectric element, wherein side surfaces of the N-type thermoelectric element and the P-type thermoelectric element facing each other are in contact;
top electrodes, separated from each other and respectively covering a portion of a top surface of the N-type thermoelectric element or a portion of a top surface of the P-type thermoelectric element; and
at least one bottom electrode, covering a bottom surface of the N-type thermoelectric element and a bottom surface of the P-type thermoelectric element.

2. The thermoelectric module as recited in claim 1, wherein the N-type thermoelectric element and the P-type thermoelectric element comprise semiconductor materials, and a charge carrier concentration of the semiconductor materials ranges between 10¹⁸ cm⁻³ and 10²¹ cm⁻³.

3. The thermoelectric module as recited in claim 1, wherein a material of the N-type thermoelectric element comprises BiTe based thermoelectric material, PbTe based thermoelectric material or SiGe based thermoelectric material.

4. The thermoelectric module as recited in claim 1, wherein a material of the P-type thermoelectric element comprises BiTe based thermoelectric material, PbTe based thermoelectric material or SiGe based thermoelectric material.

5. The thermoelectric module as recited in claim 1, wherein materials of the top electrodes and the bottom electrode respectively comprises metal or conductive metal composite material.

6. The thermoelectric module as recited in claim 1, wherein the N-type thermoelectric element and the P-type thermoelectric element respectively comprise a strip-shape, an arc-shape or a ring-shape.

7. The thermoelectric module as recited in claim 1, wherein the N-type thermoelectric element and the P-type thermoelectric element constitute a strip-shape, an arc-shape or a ring-shape.

8. The thermoelectric module as recited in claim 1, wherein when the N-type thermoelectric element and the P-type thermoelectric element respectively comprise an arc-shape or a ring-shape, or when the N-type thermoelectric element and the P-type thermoelectric element constitute an arc-shape or a ring-shape, the PN junction device is applied to a tubular heat source.

9. The thermoelectric module as recited in claim 1, wherein the top electrodes and the bottom electrode respectively comprise a strip-shape, an arc-shape or a ring-shape.

10. The thermoelectric module as recited in claim 1, wherein the number of the at least one bottom electrode in one PN junction device is one, and the bottom electrode completely covers or partially covers the bottom surface of the N-type thermoelectric element and the bottom surface of the P-type thermoelectric element.

11. The thermoelectric module as recited in claim 10, wherein the number of the at least one PN junction structure is a plurality, the PN junction structures are disposed separately, and in two adjacent PN junction structures, the top surface of the N-type thermoelectric element and the top surface of the P-type thermoelectric element separated from each other are connected by the top electrode, and the adjacent bottom electrodes do not contact each other.

12. The thermoelectric module as recited in claim 11, wherein the N-type thermoelectric element and the P-type thermoelectric element respectively comprise a strip-shape, an arc-shape or a ring-shape.

13. The thermoelectric module as recited in claim 11, wherein the N-type thermoelectric element and the P-type thermoelectric element constitute a strip-shape, an arc-shape or a ring-shape.

14. The thermoelectric module as recited in claim 1, wherein, in one PN junction device, the number of the at least one bottom electrode is a plurality, and the bottom electrodes are separated from each other and respectively cover a portion of the bottom surface of the N-type thermoelectric element or a portion of the bottom surface of the P-type thermoelectric element.

15. The thermoelectric module as recited in claim 14, wherein, in the same PN junction device, the bottom electrodes have an opening therebetween that exposes a portion of the bottom surface of the N-type thermoelectric element and a portion of the bottom surface of the P-type thermoelectric element.

16. The thermoelectric module as recited in claim 14, wherein the number of the at least one PN junction structure is a plurality, the PN junction structures are disposed separately, and the top surface of the N-type thermoelectric element and the bottom surface of the P-type thermoelectric element in one PN junction structure are respectively connected to the top surface of the P-type thermoelectric element and the bottom surface of the N-type thermoelectric element at a side through the top electrode and the bottom electrode.

17. The thermoelectric module as recited in claim 16, wherein the bottom surface of the N-type thermoelectric element and the top surface of the P-type thermoelectric element in one PN junction structure are respectively connected to the bottom surface of the P-type thermoelectric element and the top surface of the N-type thermoelectric element at another side by the bottom electrode and the top electrode.

18. The thermoelectric module as recited in claim 1, wherein a method for connecting the top electrodes with the at least one PN junction structure comprises solder bonding or direct pressing.

19. The thermoelectric module as recited in claim 1, wherein a method for connecting the bottom electrode with the at least one PN junction structure comprises solder bonding or direct pressing.

20. The thermoelectric module as recited in claim 1, wherein, in the same PN junction device, the top electrodes have an opening therebetween that exposes a portion of the top surface of the N-type thermoelectric element and a portion of the top surface of the P-type thermoelectric element.
